(19) United States
(12) Patent Application Publication
(10) Pub. No.: US 2025/0159810 A1
(43) Pub. Date: May 15, 2025

(54) PRINTED CIRCUIT BOARD ASSEMBLY

(71) Applicant: Rolls-Royce Deutschland Ltd & Co KG, Blankenfelde-Mahlow (DE)

(72) Inventors: Uwe WALTRICH, Blankenfelde-Mahlow (DE); Dipenkumar PATEL, Blankenfelde-Mahlow (DE); Gergely László HEGEDÜS-FUCHS, Budapest (HU)

(21) Appl. No.: 18/942,720

(22) Filed: Nov. 10, 2024

(30) Foreign Application Priority Data
Nov. 10, 2023 (EP) 23 209 006.8

(51) Int. Cl. H05K 1/18; H05K 1/02; H05K 3/00

(52) U.S. Cl. CPC H05K 1/181; H05K 1/021; H05K 3/0008; H05K 2201/066; H05K 2201/09781; H05K 2201/10409; H05K 2201/10522; H05K 2201/2009; H05K 2201/2072

(57) ABSTRACT

A printed circuit board assembly includes a printed circuit board having an upper side and a lower side, an electrical module having an upper side and a lower side, and a holding down construction. The upper side of the electrical module is arranged on the lower side of the printed circuit board. The holding down construction includes screwing posts that are configured to be screwed against the printed circuit board. The holding down construction is arranged on the upper side of the printed circuit board and includes contact structures that are at a distance from the screwing posts and configured to rest or press on the printed circuit board at specific contact points only. The printed circuit board includes dedicated support points that correspond to the specific contact points of the holding down construction and are contacted by the specific contact points. The dedicated support points are mechanically reinforced.

This application claims the benefit of European Patent Application No. EP 23209006.8, filed on Nov. 10, 2023, which is hereby incorporated by reference in its entirety.

### FIELD

The present disclosure relates to a printed circuit board assembly.

### BACKGROUND

It is known to press printed circuit board (PCB) based power electronics devices to a heat sink for cooling. The power electronics devices to be cooled may be configured as surface-mounted devices (SMD) or through-hole technology (THT) devices and located on the underside of the PCB. To compensate for height tolerances, it is further known to press such PCB based power electronics devices against a heat sink through a thermal interface material. As such thermal interface material reduces the cooling performance compared to a direct contact, there is a desire to reduce the thickness of such thermal interface material to the extent possible.

The use of holding down clamps represents an effective way to limit the deformation of a printed circuit board. Deformation such as a bending of a printed circuit board may be caused by thermomechanical or vibrational expansion. Preventing deformation of the printed circuit board alone already leads to an increase in lifetime and reliability. Further, by limiting the deformation of a printed circuit board through a holding down clamp, tilting of the power electronics devices attached to the underside of the PCB is reduced. Such tilting and the variation in height of the power electronics device associated with the tilting requires an increased tolerance range of a gap between the heat sink and the power electronics device in which the thermal interface material is arranged. However, an increased thickness of the gap and of the thermal interface material is associated with an increased thermal resistance.

Accordingly, there is a need to limit the thickness of the gap between the heat sink and the power electronics device and reduce the required tolerance range. One way to achieve this is to improve the holding down clamp to avoid deformation of the printed circuit board. However, there are limitations on the design of a holding down clamp, as the holding down clamp should not overly determine the design of the printed circuit board. In particular, the number of screw connections with which the holding down clamp is connected to the printed circuit board and the heat sink may be as low as possible in order to not restrict the PCB layout too much.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a printed circuit board assembly with a construction that allows to effectively reduce bending of a printed circuit board without overly limiting the layout possibility of the printed circuit board is provided.

According to an aspect of the present embodiments, a printed circuit board assembly is provided. The printed circuit board assembly includes a printed circuit board having an upper side and a lower side, and at least one electrical module having an upper side and a lower side. The at least one electrical module is arranged with its upper side on the lower side of the printed circuit board. The printed circuit board assembly also includes a holding down construction for the printed circuit board. The holding down construction includes screwing posts configured to be screwed against the printed circuit board.

In a further aspect, it is provided that the holding down construction is arranged on the upper side of the printed circuit board and includes contact structures that are configured to rest or press on the printed circuit board at specific contact points only. The contact structures are different from and at a distance from the screwing posts. The printed circuit board includes dedicated support points that correspond to the specific contact points of the holding down construction and are contacted by the specific contact points. The dedicated support points are mechanically reinforced.

Aspects of the present embodiments are thus based on the idea of providing a holding down construction that asserts a pressure on the upper surface of the printed circuit board at specific points only and to provide a printed circuit board upper surface that is mechanically reinforced at those points that receive a pressure from the holding down construction. By providing for a holding down construction that contacts the printed circuit board at specific points only, the area of the printed circuit board that lies against the holding down construction may be reduced such that the printed circuit board layout is less limited by the holding down construction. Also, by asserting a pressure on the upper surface of the printed circuit board at specific points that are located at a distance from the screwing posts, the number of pressure points may be maintained or even increased such that bending of the printed circuit board is effectively reduced while limiting the number of screwing posts and corresponding holes in the printed circuit board to a minimum. This further reduces constraints on the layout of the printed circuit board. Reinforcing the dedicated support points on the printed circuit board that receive the pressure from the holding down construction allows to effectively guide the received pressure into the printed circuit board and avoids wear and tear at the pressure points.

A further advantage associated with the present embodiments lies in that by providing effective ways that inhibit or reduce bending of the printed circuit board, the height of a gap between a heat sink and the underside of the electrical modules may be limited, and tolerances may be reduced. This further allows to implement a thermal interface material of reduced thickness, which leads to an improved heat transfer into the heat sink. Also, the reliability of the thermal coupling is improved.

For the purposes of the present embodiments, the side of the holding down construction facing the printed circuit board is always referred to as the lower side of the holding down construction, regardless of the actual spatial orientation of the holding down construction and of the printed circuit board. In the same manner, the side of the electrical module that faces the printed circuit board is always referred to as the upper side of the electrical module.

In an embodiment, the contact structures that are configured to rest or press on the printed circuit board are formed as pushing pins. The pushing pins are configured to punctually assert a pressure against the printed circuit board. The specific contact points that lie or press against the dedicated support points of the printed circuit board are formed by the face sides of the pushing pins. The pushing pins may be cylindrical. The pushing pins may be arranged on ribs formed by the holding down construction. Such ribs may form a grid-like basic structure that includes both the screwing posts and the pushing pins.

The dedicated support points that are mechanically reinforced may be reinforced in a plurality of manners. Reinforcement may provide that ways for improved mechanical resistance are provided in addition to the printed circuit board material. According to an embodiment, the dedicated support points are mechanically reinforced by at least one metal layer. In a refinement of such an embodiment, the dedicated support points are mechanically reinforced by a layer structure of the printed circuit board. The layers of the layer structure are metal layers. The metal layers are not current-carrying layers.

The purpose of the metal layers is thus to provide for the dedicated support points, without having any influence on the current carrying layers of the printed circuit board. To further improve the quality of the reinforcement, it is provided for, in an embodiment, that the mechanically reinforcing layer structure includes at least two upper metal layers connected by vias. By providing vias that are also metallized, that connect the at least two metal layers, the assembly is mechanically stiffened.

In an embodiment, the metal layers are coppers layers. In other embodiments, the metal layers are provided by a different metal such as aluminum or an aluminum alloy. Generally, the one or more metal layers that form the mechanically reinforced dedicated support points on the surface of the printed circuit board are limited in extension to a limited area that receives the pressure from the specific contact points. For example, the layers may be formed as metal pads that have a circular or rectangular form.

In a further embodiment, the electrical modules are arranged on the underside of the circuit board in parallel rows, where at least two of the parallel rows form assemblies each of four electrical modules arranged in a rectangular pattern. Each assembly of four electrical modules is associated with one dedicated support point on the upper side of the printed circuit board. Such embodiment uses one dedicated support point and, accordingly, one contact point of the holding down construction only to push down the printed circuit board in an area in which a total of four electrical modules are located, thus pressing these four electrical modules against the heat sink. Thereby, the number of contact points of the holding down construction and corresponding dedicated support points on the printed circuit board is much less than the number of electrical modules.

In a refinement of such embodiment, the dedicated support points on the upper side of the printed circuit board are positioned such that each of the respective opposite points on the lower side of the printed circuit board lies centrally between the four electrical modules of an assembly. By such central location between four electrical modules, the received pressure is provided evenly to all four electrical modules of a considered assembly.

In a further embodiment, the holding down construction is configured to rest against the upper side of the printed circuit board without providing a pressure on the printed circuit board when the printed circuit board is not bent. Accordingly, a counterforce that acts onto the printed circuit board is only provided for by the holding down construction if the printed circuit board starts to bend towards the holding down construction. By such a counterforce, a lifting of the printed circuit board in the upward direction, away from the heat sink, is prevented.

In a further embodiment, the holding down construction is configured to press on the printed circuit board under provision of a preload. The preload provides a force acting on the printed circuit board even when the printed circuit board is not bent towards the holding down construction. In this embodiment, the holding down construction always provides a pressure on the printed circuit board through its contact points. Thereby, the printed circuit board is pressed downward punctually. This embodiment is associated with the advantage that by the pressure on the printed circuit board the height of the gap between the upper surface of the heat sink and the lower surface of the electrical module is reduced. Also, a stronger force that inhibits the printed circuit board from lifting upwards is generated.

In an embodiment, to provide for a preload on the printed circuit board, the pushing pins have a length such that the pushing pins press on the upper side of the printed circuit board even if the upper side is flat and not bent.

In a further embodiment, the printed circuit board assembly further includes a heat sink having an upper side, a gap between the upper side of the heat sink and the lower side of the electrical module, and a heat-conducting material. The heat-conducting material is arranged in the gap, and the at least one electrical module is thermally coupled at its lower side to the heat sink through the heat-conducting material. According to the present embodiments, such gap may be minimized by providing for an effective holding down construction.

In an embodiment, the dedicated support points on the printed circuit board have a circular or rectangular form. However, in principle, the dedicated support points may have different forms as well, such as an elliptical form. The dedicated support points have a closed perimeter.

In a further embodiment, the printed circuit board assembly further includes a positioning system that positions the holding down construction with respect to the printed circuit board. The positioning system includes pre-assembly features in the holding down construction and in the printed circuit board. By implementing a positioning system, tolerances are reduced, which allows for the reduction of the area of the dedicated support points on the printed circuit board. By reducing the area of the dedicated support points, additional space is provided for the layout of the printed circuit board and components located thereon.

In an embodiment, the positioning system includes two positioning pins that are arranged in the heat sink and, as pre-assembly features, positioning holes in the printed circuit board and in the holding down construction. The positioning pins extend from the heat sink through the printed circuit board positioning holes and the holding down construction positioning holes. Accordingly, tolerances are reduced by orienting the printed circuit board and the holding down construction in accordance with two positioning pins fixed to the heatsink. The positioning pins pass through holes in the printed circuit board and in the holding down construction.

The implementation may be such that the holes in the printed circuit board and in the holding down construction that serve to pass one of the pins through are circular, and that the holes in the printed circuit board and in the holding down construction that serve to pass the other of the pins through are oblong holes. The circular holes provide for an exact positioning point of the holding down construction with respect to the printed circuit board. The oblong holes provide for a second positioning point. The oblong shape takes into account potential small tolerances in the position of the preassembly features (e.g., the 20 holes) in the holding down construction and in the printed circuit board.

The holding down construction may be configured as a 3D printed part. However, other forms of manufacture such as casting or injection molding are possible as well. In embodiments, each of the electrical modules includes a power semiconductor device. The electric contacts of the electrical modules are located at the upper side and electrically connected to respective electric contacts at the lower side of the printed circuit board. For example, each electrical module includes three electric contacts in the form of solder pads at the upper side that provide for a gate voltage, a drain voltage, and a source voltage for the power semiconductor device. At the lower side, the electrical module may form a thermal interface that is electrically insulated from the power semiconductor device. One or more ceramic layers may be included in the electrical module. Such electrical modules are also referred to as prepackage modules. The thermal interface of the electrical module may be thermally coupled to a heat sink. A thermal interface material may be arranged between the thermal interface of the electrical module and the heat sink.

The skilled person will appreciate that except where mutually exclusive, a feature or parameter described in relation to any one of the above aspects may be applied to any other aspect. Further, except where mutually exclusive, any feature or parameter described herein may be applied to any aspect and/or combined with any other feature or parameter described herein.

### BRIEF DESCRIPTION OF THE DISCLOSURE

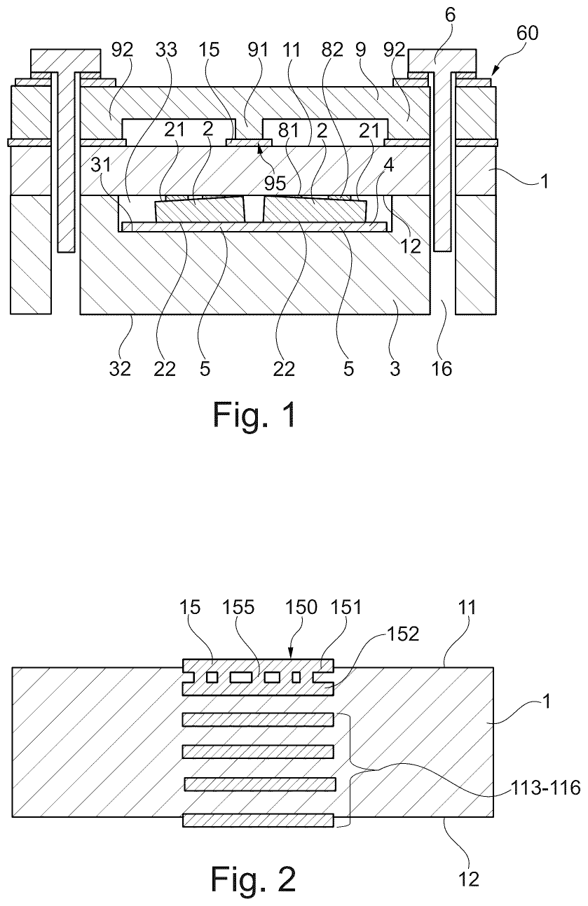

FIG. 1 shows an embodiment of a printed circuit board assembly including a printed circuit board and a holding down construction, where the holding down construction includes a contact structure that rests on the printed circuit board at a specific contact point, and where the printed circuit board includes a mechanically reinforced support point corresponding to the specific contact point;

FIG. 2 is an enlarged view of an example embodiment of the mechanically reinforced support point of FIG. 1;

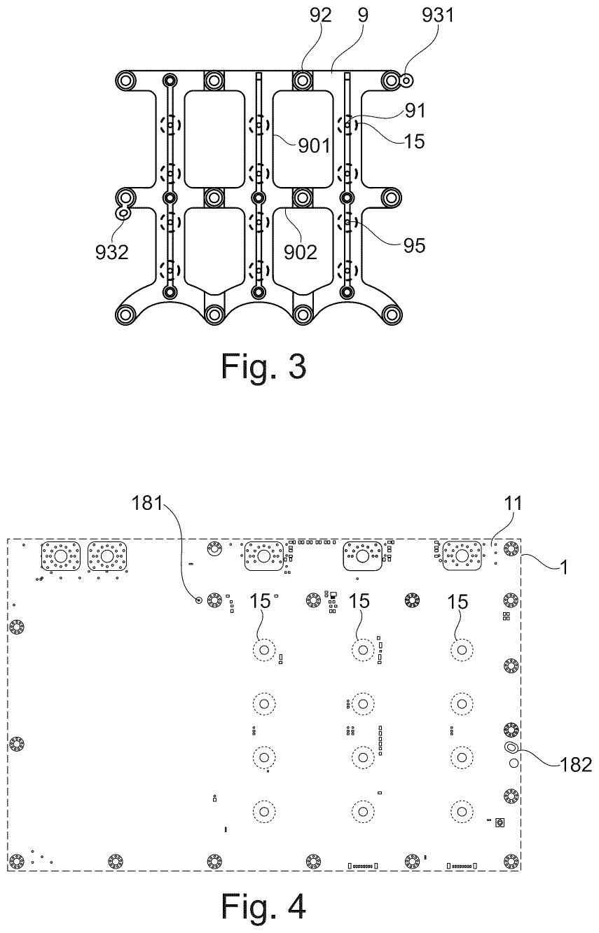

FIG. 3 shows an example holding down construction for a printed circuit board assembly, the holding down construction including ribs on which pushing pins are arranged as contact structure;

FIG. 4 is a top view of an example printed circuit board that includes a plurality of mechanically reinforced support points;

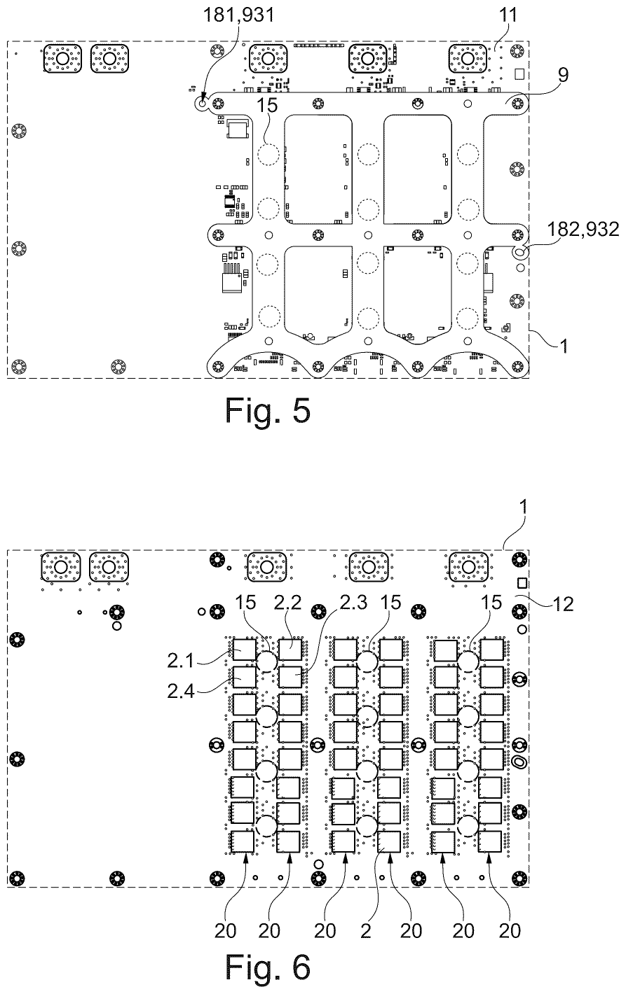

FIG. 5 is a top view on the printed circuit board of FIG. 4 when the holding down construction of FIG. 3 is connected to the printed circuit board;

FIG. 6 is a bottom view of the printed circuit board of FIGS. 3 and 4, where a plurality of electrical modules are arranged in a number of rows on the lower side of the printed circuit board, whereby the mechanically reinforced support points on the upper side of the printed circuit board are also shown schematically;

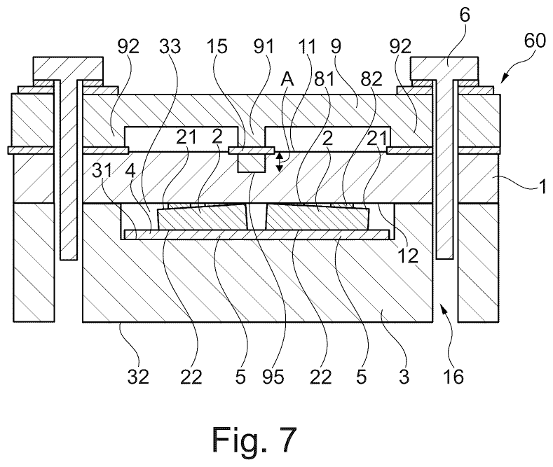

FIG. 7 is a further embodiment of a printed circuit board assembly including a printed circuit board and a holding down construction, where the holding down construction includes a contact structure that presses on the printed circuit board at a specific contact point, and where the printed circuit board includes a mechanically reinforced support point corresponding to the specific contact point;

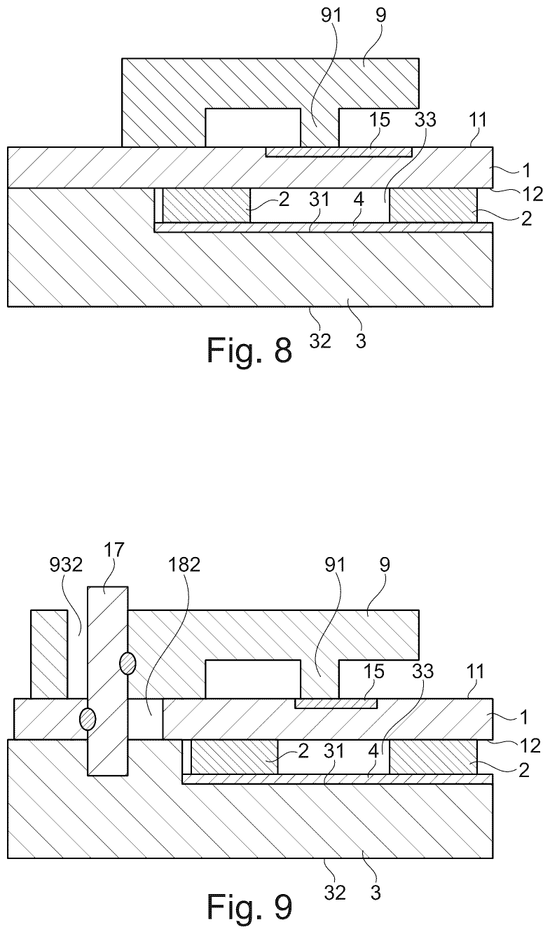

FIG. 8 shows schematically a section of a printed circuit board assembly similar to that of FIG. 1, where a dedicated support point of the printed circuit board against which a pushing pin of the holding down construction rests is depicted with an exaggerated size that is due to tolerances; and

FIG. 9 shows schematically a section of a printed circuit board assembly similar to that of FIG. 1, where the printed circuit board assembly also includes a tolerance reducing positioning system that includes pins attached to the heat sink and holes in the printed circuit board and in the holding down construction.

### DETAILED DESCRIPTION

FIG. 1 shows a printed circuit board assembly including a printed circuit board 1 having an upper side 11 and a lower side 12, electrical modules 2 having an upper side 21 and a lower side 22, and a heat sink 3 having an upper side 31 and a lower side 32.

The printed circuit board 1 includes a plurality of printed circuit board layers (not shown separately) arranged one above the other, the uppermost printed circuit board layer forming the upper side 11 and the lowermost printed circuit board layer forming the lower side 12.

The upper side 21 of the electrical modules 2 are arranged on the lower side 12 of the printed circuit board 1. FIG. 1 shows two electrical modules 2, but this is only to be understood as an example. A number of (e.g., several) such electrical modules 2 may be arranged one behind the other, thereby forming rows (e.g., whereby the other electrical modules of a row are not visible in FIG. 1), and a different number of electrical modules 2 or rows of electrical modules 2 may be arranged next to each other.

The connection of an electrical module 2 to the printed circuit board 1 is made, for example, by surface mounting. In this case, electrical contacts on the upper side of the electrical module 2 (not shown separately) are electrically connected to corresponding electrical contacts on the lower side 12 of the printed circuit board 11 (not shown separately) via solder connections 81, 22. For example, each electrical module 2 includes electrical contacts for a source terminal, a gate terminal, and a drain terminal of the electrical module 2.

Between the upper side 22 of the electrical module 2 and the lower side 12 of the printed circuit board 1, a gap caused by the solder connections 81, 82 that is filled with an underfill material (not shown separately) is present.

The electrical module 2 may be formed in a variety of ways. In embodiments, the electrical module 2 includes a semiconductor device (e.g., a power semiconductor such as, a power MOSFET or an IGBT device). The semiconductor device is arranged, for example, on a ceramic carrier (not shown separately) that is configured to electrically insulate the semiconductor component from the heat sink and to thermally connect the semiconductor device to the heat sink. The electrical module 2 is also referred to as a prepackage module.

The electrical modules 2 may not be completely horizontally aligned but are arranged tilted on the underside of the printed circuit board 1. For example, such tilting is present due to a bending of the printed circuit board 1 caused by thermomechanical or vibrational expansion, while other factors such as an unequal thickness of the solder with which the electrical modules 2 are electrically connected on the underside of the printed circuit board 1 also play a role.

The electrical modules 2 require cooling by the heat sink 3. For this purpose, the electrical modules 2 are arranged in a cavity or recess 33 of the heat sink 3. The modules 2 to be cooled protrude into the recess 33 and come into thermal contact with the heat sink 3 on their underside through a thermal interface material 4 that is located in a gap 5 between the upper side 31 of the heat sink 3 and the low side 22 of the electrical module 2. By preventing or reducing deformation of the printed circuit board 1, the height of the gap 5 may be constructed to be small, thereby maximizing a heat flow from the electrical modules 2 into the heat sink 3.

In order to reduce or avoid deformation of the printed circuit board 1 (e.g., with the consequence that the gap 5 and the thermal interface material 4 arranged therein may be configured to have a small thickness), the printed circuit board arrangement further includes a holding down construction 9 (in the following, also referred to as holding down clamp). The holding down clamp 9 includes screwing posts 92 that allow screws 6 to connect the holding down clamp 9 with the printed circuit board 1 and the heat sink 3. The screws 6 are screwed into through holes 16 that extend from the holding down clamp 9 over the printed circuit board 1 into the heat sink 3. The screws 6 bear on the top side of the holding down clamp 9 via washers and/or mentalizations 60. Using the screws 6, the holding down clamp 9 is pressed against the upper side of the printed circuit board 1, and consequently, the electrical modules 2 are pressed against the heat sink 3.

The holding down clamp 9 further includes contact structures that are formed by a pushing pin 91. The pushing pin 91 is arranged at a distance from the screwing posts 92. A number of (e.g., several) such pushing pins 91 may be provided at a distance to each other. The pushing pins 91 include a lower face side 95 that rests on the printed circuit board upper surface 11 when the printed circuit board 1 is not bent upwards and punctually asserts a pressure against the printed circuit board 1 when the printed circuit board 1 is bending upwards. The lower face side 95 represents a contact point of the holding down construction 9 for contacting the upper surface 11 of the printed circuit board 1.

Further, the printed circuit board 1 includes a dedicated support point 15 that corresponds in location to the specific contact point 95. The lower face side 95 of the pushing pin 91 rests against the dedicated support point 15. The dedicated support point 15 is mechanically reinforced as will be discussed with respect to FIG. 2.

In case the printed circuit board 1 is flat/not bent, the holding down clamp 9 does not provide a force on the printed circuit board 1. However, a punctual counterforce is provided in case the printed circuit board 1 bends upwards due to a deformation, thereby avoiding or reducing a lifting and bending of the printed circuit board 1 away from the heat sink 3.

The heat sink 3 may be made of a metal such as aluminum or an aluminum alloy and may have cooling fins (not shown). The heat sink 3 may be an active heat sink that is actively cooled by a fan or by liquid cooling or may alternatively be a passive heat sink.

FIG. 2 shows an embodiment of the mechanical reinforcement of the dedicated support point 15. In FIG. 2, the printed circuit board 1 is shown only. The printed circuit board 1 includes an upper side 11 and a lower side 12. Further, the printed circuit board 1 includes a plurality of current carrying copper layers 113-116 and isolating layers in between in a usual manner known to the skilled person. To implement a reinforcement of the support points 15, a layer structure 150 is provided in the area of the support point 15. The layer structure 150 includes two upper copper layers 151, 152 that are connected vertically by metallized vias 155. Upper layer 151 is on the upper side 12 of the printed circuit board 1. By providing a number of (e.g., several) copper layers 151, 152 at the top surface of the printed circuit board, the support point 15 is mechanically reinforced. A further stiffening and mechanical reinforcement are achieved by the vertical vias 155.

The layer structure 150 with layers 151, 152 and vias 155 does not serve to guide any current. The layers 151, 152 are not current-carrying layers and not electrically connected to the other layers 113-116 of the printed circuit board. The layers 151, 152 may have the form of circular or rectangular pads of limited size.

FIG. 3 shows an example of a holding down clamp 9 in a view on the bottom side of the holding down clamp 9. The holding down clamp 9 includes a grid-like basic structure that is formed by first ribs 901 and second ribs 902 generally arranged in a perpendicular manner. The holding down clamp 9 further includes screwing posts 92 that are configured to be screwed against a printed circuit board and a heat sink, as discussed with respect to FIG. 1. The screwing posts 92 are configured to receive a screw that allows the screwing posts 92 to be screwed onto a printed circuit board and heat sink. The screwing posts 92 are attached to the second ribs 902 and arranged at a distance to each other.

The holding down clamp 9 further includes contact structures that are attached to the lower side of the basic structure, thus facing the printed circuit board. The contact structures provide for a downward pressure on the printed circuit board that inhibits the printed circuit board to bend towards the holding down clamp 9. In the depicted embodiment, the contact structures are formed as pins 91 (e.g., pushing pins 91), as the contact structures push against the printed circuit board. The pushing pins 91 are arranged along the first ribs 901 and at a distance to each other. In other embodiments, pushing pins 91 may be provided along the second ribs 902 additionally or alternatively.

In FIG. 3, in addition to the pushing pins 91, the location of the corresponding dedicated support points 15 on the top surface of a printed circuit board to which the holding down clamp 9 is connected is also shown to indicate the positional relationship.

The holding down clamp 9 further includes as pre-assembly features a positioning hole 931 that is circular and a further positioning hole 932 that is oblong, as will be discussed with respect to FIG. 9.

The holding down clamp 100 may be formed by 3D-printing.

FIG. 4 is a top view of an example printed circuit board 1, where the upper surface 11 of the printed circuit board 1 is visible. On the upper surface 11, a plurality of mechanically reinforced support points 15 are implemented. The reinforced support points 15 may be formed as shown in FIG. 2 or in any other manner providing for a reinforcement of the support points 15. Other reinforcement may include one or a number of (e.g., several) non-metal layers such as a resin having a mechanical strength higher than that of typical printed circuit board isolating layer material (e.g., glass-reinforced epoxy laminate material FR4).

The printed circuit board 1 further includes as pre-assembly features a positioning hole 181 that is circular and a further positioning hole 182 that is oblong, as will be discussed with respect to FIG. 9.

FIG. 5 shows the holding down clamp 9 of FIG. 3 when arranged on the upper side 11 of the printed circuit board 1 of FIG. 4. The mechanically reinforced support points are also indicated (e.g., while in fact being concealed by the holding down clamp 9). The pusher pins 91 punctually assert a pressure against the printed circuit board 1 when the printed circuit board 1 bends towards the holding down clamp 9.

As shown in FIG. 5, the positioning holes 181, 182 of the printed circuit board 1 and the positioning holes 931, 932 of the holding down construction 9 are arranged above each other when the holding down clamp 9 is arranged on the upper side 11 of the printed circuit board 1. Two pins extend through holes 181, 931 and 182, 932, as will be discussed with respect to FIG. 9.

FIG. 6 shows the lower side 12 of the printed circuit board 1 of FIGS. 4 and 5. On the lower side 12, as discussed before, a plurality of electrical modules 2 are arranged. The electrical modules 2 are arranged in parallel rows 20. More particularly, in the depicted embodiment, electrical modules 2 are arranged in six parallel rows 20 each including 8 electrical modules. The electrical modules 2 are interconnected and form, for example, logical switches of a three-phase inverter with three phases U, V, W. However, this is only to be understood as an example.

FIG. 6 also indicates the position of the support points 15 that are located on the upper side of the printed circuit board 1. It is provided that each support point 15 is associated with four of the electrical modules 2. The electrical modules 2 of two adjacent rows 20 form a plurality of assemblies each including four of the electrical modules 2 arranged in a rectangular pattern. For example, as depicted in FIG. 6, one of the support points 15 (or rather its opposite point on the lower side 12 of the printed circuit board 1) lies centrally between the four electrical modules 2.1, 2.2, 2.3 and 2.4 of two adjacent rows 20. This provides that the printed circuit board 1 is effectively pressed against the heat sink 3 in the area of the electrical modules 2 via the respective pushing pins 91, as shown in FIG. 1, while limiting the number of pushing pins 91.

FIG. 7 is a further embodiment of a printed circuit board assembly. The printed circuit board assembly of FIG. 7 differs from the printed circuit board assembly of FIG. 1 in one aspect only, such that for the other aspects and features, reference is made to the description of FIG. 1. The difference lies in that, while in FIG. 1 the pushing pins 91 are configured to rest against the upper side 11 of the printed circuit board without providing a force on the printed circuit board when the printed circuit board is not bent upwards, in FIG. 7, the pushing pins 91 provide a preload on the printed circuit board 1 even if the printed circuit board 1 is not bending towards the holding down clamp 9.

To achieve such a preload, the pushing pins 91 are longer than in FIG. 1. The increase in length of the pushing pins 91 compared to the embodiment of FIG. 1 may be in the range between 0.1 mm and 0.5 mm. The pushing pins 91 include a length such that the pushing pins 91 press on the upper side 11 of the printed circuit board 1 even if the upper side 1 is not bent towards the holding down clamp 9. Thereby, the printed circuit board 1 is punctually pressed downward towards the heat sink 3 such that the distance between the heat sink 3 and the lower side 2 of the electrical modules 2 (e.g., the height of the gap 5) is reduced.

FIG. 7 is schematic in that FIG. 7 only shows pushing pins 91 of increased length, without showing the corresponding bending and vertical movement of the printed circuit board 1 and of the support points 15. Arrow A indicates that the vertical position of the lower face side 95 (e.g., which is the contact point of the pushing pin 91 with the upper surface 11 of the printed circuit board 1) changes depending on the bending status of the printed circuit board 1.

FIG. 8 shows a section of a printed circuit board assembly similar to that of FIG. 1, depicting a holding down construction 9 including a pushing pin 91 that rests against or presses on the upper side 11 of a printed circuit board 1 at a dedicated support point 15 that is mechanically reinforced. FIG. 8 further shows schematically two electrical modules 2 located at the lower side 12 of the printed circuit board 1, a heat conducting material 4, and a heat sink 3. The heat sink 3 has a cavity 33, an upper side 31 and a lower side 32.

Due to tolerances in the relative positions of the holding down construction 9 and the printed circuit board 1, the dedicated support points 15 that are contacted by the pushing pins 91 may need to have a larger area than desired (as schematically illustrated in FIG. 8), thereby reducing space for the printed circuit board layout and components attached to the printed circuit board.

To reduce the tolerances and allow to shrink the size of the area of the dedicating support points 15, a tolerance reducing positioning system is provided in the embodiment of FIG. 9. The positioning system makes use of the pre-assembly features 181, 182, 931, 932 of the printed circuit board 1 and of the holding down construction 9 shown in FIGS. 3, 4 and 5, where in FIG. 9, only the pre-assembly features 182, 932 are depicted. More particularly, two positioning pins 17 are formed by or attached to the heat sink 9, where one of the positioning pins 17 is depicted in FIG. 9. The depicted positioning pin 17 extends from the heat sink 3 through the positioning hole 182 in the printed circuit board 1 and through the positioning hole 932 in the holding down construction 9. In a similar manner, the other positioning pin 17 extends from the heat sink 3 through positioning hole 181 of the printed circuit board 1 and positioning hole 932 of the holding down construction 9 (see FIGS. 3, 4, and 5).

Further, as discussed before, the positioning holes 182, 932 are oblong, where the other positioning holes 181, 131 are circular. This allows to fix the relative position between the holding down construction 9 and the printed circuit board 1 with minimal tolerances, thereby allowing the area of the mechanically reinforced support points 15 to be minimal, as is schematically shown in FIG. 9. Further, the dimensions are defined such to provide a minimum clearance in all tolerance cases.

The above description is intended for illustrative purposes only and is not intended to limit the scope of the present disclosure in any way. Also, those skilled in the art will appreciate that other aspects of the disclosure may be obtained from a study of the drawings, the disclosure, and the appended claims. All methods described herein may be performed in any suitable order unless otherwise indicated herein or otherwise clearly contradicted by context. Various features of the various embodiments disclosed herein may be combined in different combinations to create new embodiments within the scope of the present disclosure. In particular, the disclosure extends to and includes all combinations and sub-combinations of one or more features described herein. Any ranges given herein include any and all specific values within the range and any and all sub-ranges within the given range.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A printed circuit board assembly comprising:
a printed circuit board having an upper side and a lower side;
at least one electrical module having an upper side and a lower side, the upper side of an electrical module of the at least one electrical module being arranged on the lower side of the printed circuit board; and
a holding down construction for the printed circuit board, the holding down construction comprising screwing posts that are configured to be screwed against the printed circuit board,
wherein the holding down construction is arranged on the upper side of the printed circuit board and comprises contact structures that are at a distance from the screwing posts and configured to rest or press on the printed circuit board at specific contact points only,
wherein the printed circuit board comprises dedicated support points that correspond to the specific contact points of the holding down construction and are contacted by the specific contact points, and
wherein the dedicated support points are mechanically reinforced.

2. The printed circuit board assembly of claim 1, wherein the contact structures that are configured to rest or press on the printed circuit board are formed as pushing pins configured to punctually assert a pressure against the printed circuit board, and
wherein the specific contact points are formed by face sides of the pushing pins that rest against the dedicated support points of the printed circuit board.

3. The printed circuit board assembly of claim 1, wherein the pushing pins are arranged on ribs formed by the holding down construction.

4. The printed circuit board assembly of claim 1, wherein the dedicated support points are mechanically reinforced by at least one metal layer.

5. The printed circuit board assembly of claim 4, wherein the dedicated support points are mechanically reinforced by a layer structure, layers of the layer structure being metal layers, and
wherein the metal layers are not current-carrying layers.

6. The printed circuit board assembly of claim 5, wherein the mechanically reinforcing layer structure comprises at least two upper metal layers connected by vias.

7. The printed circuit board assembly of claim 1, wherein the at least one electrical module comprises a plurality of electrical modules,
wherein the plurality of electrical modules are arranged on the lower side of the circuit board in parallel rows,
wherein at least two of the parallel rows form assemblies, each of the assemblies including four electrical modules of the plurality of electrical modules arranged in a rectangular pattern, and
wherein each of the assemblies of four electrical modules is associated with one dedicated support point on the upper side of the printed circuit board.

8. The printed circuit board assembly of claim 7, wherein the dedicated support points on the upper side of the printed circuit board are positioned such that each of the respective opposite points on the lower side of the printed circuit board lies centrally between the four electrical modules of an assembly of the assemblies.

9. The printed circuit board assembly of claim 1, wherein the holding down construction is configured to rest against the upper side of the printed circuit board without providing a pressure on the printed circuit board when the printed circuit board is not bent towards the holding down construction.

10. The printed circuit board assembly of claim 2, wherein the holding down construction is configured to press on the printed circuit board under provision of a preload, the preload providing a force acting on the printed circuit board even when the printed circuit board is not bent towards the holding down construction.

11. The printed circuit board assembly of claim 10, wherein the pushing pins have a length such that the pushing pins press on the upper side of the printed circuit board even when the upper side is not bent.

12. The printed circuit board assembly of claim 1, further comprising:
a heat sink having an upper side;
a gap between the upper side of the heat sink and the lower side of the electrical module; and
a heat-conducting material,
wherein the heat-conducting material is arranged in the gap, and
wherein the lower side of the at least one electrical module is thermally coupled to the heat sink through the heat-conducting material.

13. The printed circuit board assembly of claim 12, further comprising:
a positioning system configured to position the holding down construction with respect to the printed circuit board,
wherein the positioning system comprises pre-assembly features in the printed circuit board and in the holding down construction.

14. The printed circuit board assembly of claim 13, wherein the positioning system comprises two positioning pins that are arranged in the heat sink, and printed circuit board positioning holes in the printed circuit board and holding down construction positioning holes in the holding down construction,
wherein the positioning pins extend from the heat sink through the printed circuit board positioning holes and the holding down construction positioning holes.

15. The printed circuit board assembly of claim 14, wherein one printed circuit board positioning hole of the printed circuit board positioning holes and one holding down construction positioning hole of the holding down construction positioning holes configured to pass one of the two positioning pins through are circular holes, and
wherein the other circuit board positioning hole of the printed circuit board positioning holes and the other holding down construction positioning hole of the holding down construction positioning holes configured to pass the other of the two positioning pins through are oblong holes.
